(19) United States
(12) Patent Application Publication
(10) Pub. No.: US 2025/0128428 A1
(43) Pub. Date: Apr. 24, 2025

(54) HAND OF INDUSTRIAL ROBOT AND INDUSTRIAL ROBOT

(71) Applicant: NIDEC INSTRUMENTS CORPORATION, Nagano (JP)

(72) Inventors: Shigeyuki KAINO, Nagano (JP); Toshiyuki Kobayashi, Nagano (JP); Ryota HORIUCHI, Nagano (JP)

(73) Assignee: NIDEC INSTRUMENTS CORPORATION, Nagano (JP)

(21) Appl. No.: 18/908,819

(22) Filed: Oct. 8, 2024

(30) Foreign Application Priority Data
Oct. 20, 2023 (JP) 2023-180778

(51) Int. Cl. B25J 15/00

(52) U.S. Cl. CPC B25J 15/0019; B25J 15/0014

(57) ABSTRACT

A hand of an industrial robot that conveys a conveyance object includes: a mounting section constituting a portion of the hand on a second direction side and having the conveyance object disposed on an upper side; a hand base constituting a portion of the hand on a third direction side and having an end of the mounting section on the third direction side attached thereto; a first support member fixed to an upper surface of the mounting section and supporting a portion of the conveyance object on the second direction side from below; a second support member supporting a portion of the conveyance object on the third direction side from below; and a first moving mechanism moving the second support member in the first direction. The first supporting member is formed with first and second support surfaces, and the second support member is formed with third and fourth support surfaces.

### CROSS REFERENCE TO RELATED APPLICATION

The present invention claims priority under 35 U.S.C. § 119 to Japanese Application No. 2023-180778 filed Oct. 20, 2023, and the entire content of which is incorporated herein by reference.

### BACKGROUND

### Field of the Invention

The present invention relates to a hand of an industrial robot used in an industrial robot that conveys a conveyance object. The present invention also relates to an industrial robot including such a hand.

### Description of the Related Documents

Conventionally, a hand (hand unit) used in a conveyance apparatus that conveys a semiconductor wafer is known (see, for example, Japanese Patent No. 6276317). The hand described in Japanese Patent No. 6276317 includes a plate-like hand member on which a semiconductor wafer is placed, a base unit to which a root portion of the hand member is fixed, two first support members, two second support members, and two third support members that support a lower surface of the semiconductor wafer, and two holding members to hold the semiconductor wafer placed on the hand member. The hand member is formed in a U-shape having a pair of finger portions, and the pair of finger portions are connected at the root portion.

In the hand described in Japanese Patent No. 6276317, the first support member is fixed to an upper surface of a tip end of the finger portion. The two second support members are fixed to an upper surface of the root portion of the hand member. The two third support members are movably disposed on the root portion. The two holding members are disposed on the root portion side and are disposed on both sides of the root portion in such a way as to sandwich the root portion. The base unit incorporates a drive unit that moves the two third support members with respect to the hand member and a drive unit that moves the two holding members with respect to the hand member.

In the hand described in Japanese Patent No. 6276317, a first support portion to support a semiconductor wafer at a predetermined first support height and a second support portion to support the semiconductor wafer at a second support height higher than the first support height are formed on the first support member. The semiconductor wafer disposed at the first support height is supported by the first support portion of the first support member and the second support member. The semiconductor wafer disposed at the second support height is supported by the second support portion of the first support member and the third support member.

In the hand described in Japanese Patent No. 6276317, the second support member is fixed to the upper surface of the root portion of the hand member, and overlaps the hand member in an up-down direction. Further, in this hand, the third support member is movably disposed on the root portion, and overlaps the hand member in the up-down direction. Therefore, in the hand described in Japanese Patent No. 6276317, a thickness of the hand in the up-down direction is likely to be increased.

Therefore, at least an embodiment of the present invention provides a hand of an industrial robot that conveys a conveyance object, which can be made thinner in an up-down direction, even when the hand includes a support member to support the conveyance object from below at least two different heights. Moreover, at least an embodiment of the present invention provides an industrial robot including such a hand.

### SUMMARY

In order to solve the above-described problem, a hand of an industrial robot according to one aspect of the present invention is an industrial robot that conveys a conveyance object, in which, a predetermined direction orthogonal to an up-down direction is defined as a first direction, one side of the first direction is defined as a second direction side, and a side opposite to the second direction side is defined as a third direction side, wherein the hand includes: a mounting section that constitutes a portion of the hand on the second direction side and of which the conveyance object is disposed on an upper side; a hand base that constitutes a portion of the hand on the third direction side and to which an end of the mounting section on the third direction side is attached; a first support member that is fixed to an upper surface of the mounting section and that supports a portion of the conveyance object on the second direction side from below; a second support member that supports a portion of the conveyance object on the third direction side from below; and a first moving mechanism that moves the second support member in the first direction, wherein the first support member is formed with a first support surface to support the conveyance object at a predetermined first height and a second support surface to support the conveyance object at a second height higher than the first height, the second support member is formed with a third support surface to support the conveyance object at the first height and a fourth support surface to support the conveyance object at the second height, and the second support member is disposed at a position shifted from the mounting section when viewed from the up-down direction.

In the hand of the industrial robot according to this aspect, the second support member on which the third support surface to support the conveyance object at the first height and the fourth support surface to support the conveyance object at the second height are formed is disposed at a position shifted from the mounting section when viewed from the up-down direction. Namely, in this aspect, the second support member does not overlap the mounting section in the up-down direction. Therefore, in this aspect, even when the hand includes the second support member to support the conveyance object from below at least two different heights, it is possible to make the hand thinner in the up-down direction as compared with a case where the second support member overlaps the mounting section in the up-down direction.

Further, in this aspect, since the third support surface to support the conveyance object at the first height and the fourth support surface to support the conveyance object at the second height are formed on the second support member, the number of components of the hand can be reduced and an installation space of the second support member can be narrowed as compared with a case where the second support member and the third support member formed separately are provided as in the hand described in Japanese Patent No. 6276317.

In this aspect, for example, the hand includes a pressing member that is configured to come into contact with an end surface of the conveyance object and press the conveyance object from the third direction side, and a second moving mechanism that is configured to move the pressing member in the first direction. The first support member is formed with an abutting surface on which the end surface of the conveyance object abuts, and the pressing member is configured to press the end surface of the conveyance object on the abutting surface and is disposed at a position shifted from the mounting section when viewed from the up-down direction. In this case, even when the hand includes the pressing member, it becomes possible to make the hand thinner in the up-down direction.

In this aspect, it is preferable that, a direction orthogonal to the up-down direction and the first direction is defined as a fourth direction, the mounting section includes: a first mounting portion and a second mounting portion, which are disposed in a state of being spaced apart from each other in the fourth direction, and a connecting portion that connects an end of the first mounting portion on the third direction side and an end of the second mounting portion on the third direction side, wherein the second support member and the pressing member are disposed between the first mounting portion and the second mounting portion in the fourth direction and on the second direction side of the connecting portion. With this configuration, it is possible to reduce a size of the hand in the first direction and the fourth direction.

In this aspect, for example, the hand includes two of the second support members disposed in a state of being spaced apart from each other in the fourth direction, and the pressing member is disposed between the two second support members in the fourth direction.

The hand according to this aspect can be used for an industrial robot including an arm to which the hand is connected and a main-body section to which the arm is connected. In this industrial robot, even when the hand includes the second support member to support the conveyance object from the lower side at least two different heights, it is possible to make the hand thinner in the up-down direction.

As described above, according to the aspect of the present invention, in the hand of the industrial robot that conveys the conveyance object, even when the support member to support the conveyance object from below at least two different heights is provided, the hand can be made thinner in the up-down direction.

### BRIEF DESCRIPTION OF THE DRAWINGS

Embodiments will now be described, by way of example only, with reference to the accompanying drawings which are meant to be exemplary, not limiting, and wherein like elements are numbered alike in several figures, in which:

FIG. 1 is a plan view for describing a schematic configuration of an industrial robot according to an embodiment of the present invention;

FIG. 2 is a plan view of a hand illustrated in FIG. 1;

FIG. 3 is a perspective view of a tip end side portion of the hand illustrated in FIG. 2;

FIG. 4 illustrates plan views for describing operations of a second support member and a pressing member illustrated in FIG. 2; and

FIG. 5 is a plan view for describing a configuration of a hand according to another embodiment of the present invention.

### DETAILED DESCRIPTION

Embodiments of the present invention will be described below with reference to the drawings.

### [Schematic Configuration of Industrial Robot]

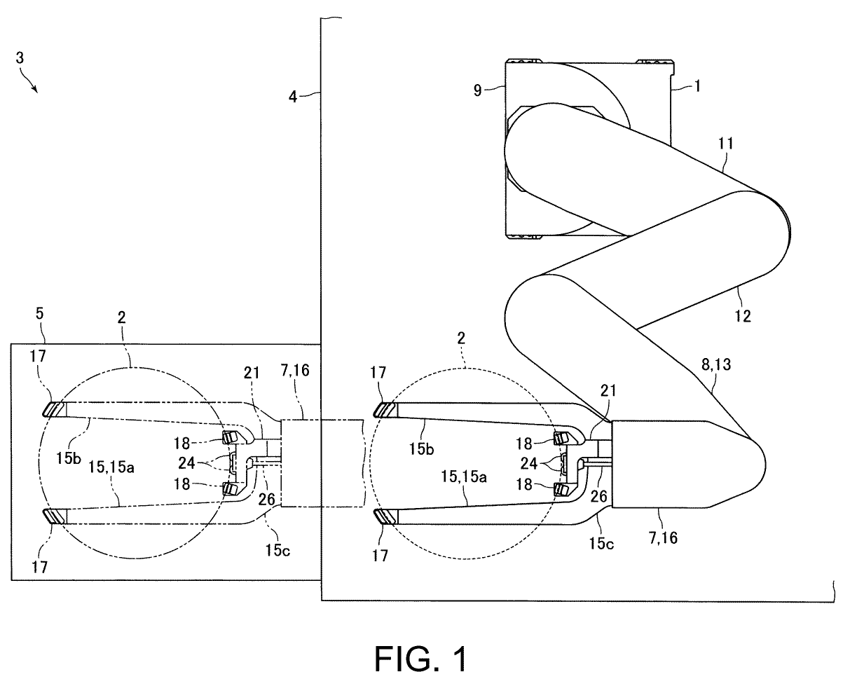

FIG. 1 is a plan view for describing a schematic configuration of an industrial robot 1 according to an embodiment of the present invention.

The industrial robot 1 (hereinafter, referred to as a “robot 1”) of the present embodiment is a horizontal articulated robot for conveying a semiconductor wafer 2 (hereinafter, referred to as a “wafer 2”) which is a conveyance object. The wafer 2 is formed in a thin disk shape. The robot 1 is incorporated and used in a semiconductor manufacturing system 3. The semiconductor manufacturing system 3 includes, for example, an equipment front end module (EFEM) 4 and a wafer processing device 5 that conducts a predetermined process on the wafer 2. In the wafer processing device 5, for example, the wafer 2 is cleaned. The robot 1 constitutes a part of the EFEM 4. The robot 1 carries the wafer 2 into the wafer processing device 5 and carries out the wafer 2 from the wafer processing device 5.

The robot 1 includes a hand 7 on which the wafer 2 is mounted, an arm 8 to which the hand 7 is connected, and a main-body section 9 to which the arm 8 is connected. The hand 7 is rotatably connected to a tip end side of the arm 8. A base end side of the arm 8 is rotatably connected to the main-body section 9. The arm 8 includes an arm section 11 whose base end side is rotatably connected to the main-body section 9, an arm section 12 whose base end side is rotatably connected to a tip end side of the arm section 11, and an arm section 13 whose base end side is rotatably connected to a tip end side of the arm section 12.

The arm sections 11 to 13 rotate with an up-down direction as an axial direction of rotation. The arm 8 moves in a horizontal direction. The hand 7 is formed to have a substantially Y shape when viewed from the up-down direction, and a tip end side of the hand 7 is bifurcated. The hand 7 is rotatably connected to a tip end side of the arm section 13. The hand 7 rotates with an up-down direction as the axial direction of rotation. The main-body section 9 includes: a columnar member to which the base end side of the arm section 11 is rotatably connected, and a lifting and lowering mechanism configured for lifting and lowering the columnar member together with the arm 8. The base end side of the arm section 11 is rotatably connected to an upper end of the columnar member. The main-body section 9, the arm section 11, the arm section 12, the arm section 13, and the hand 7 are disposed in this order from below in the up-down direction.

The robot 1 further includes: a rotating mechanism configured for rotating the columnar member and the lifting and lowering mechanism of the main-body section 9 with the up-down direction as the axial direction of rotation, an arm section drive mechanism configured for rotating the arm sections 11 and 12 and expanding and contracting a part of the arm 8 including the arm sections 11 and 12, an arm section drive mechanism configured for rotating the arm section 13, and a hand drive mechanism configured for rotating the hand 7. When the wafer 2 is conveyed to the wafer processing device 5, the hand 7 rotates with respect to the arm 8 and the arm 8 expands and contracts with respect to the main-body section 9 in such a way that, the hand 7 moves linearly in a state in which the hand 7 faces a certain direction.

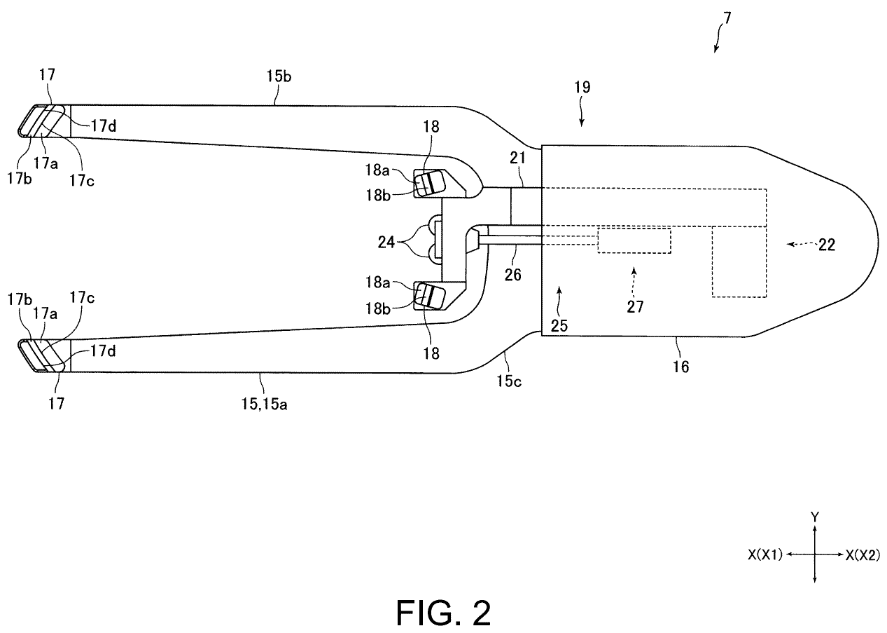

Hereinafter, a specific configuration of the hand 7 will be described. In the following description, a longitudinal direction (an X direction in FIG. 2 and the like) of the hand 7 having a substantially Y shape when viewed from an up-down direction is defined as a “front-rear direction”, and a Y direction in FIG. 2 and the like, which is orthogonal to the front-rear direction, is defined as a “left-right direction”. Namely, an X direction orthogonal to an up-down direction (a vertical direction) is defined as a front-rear direction, and a Y direction orthogonal to the up-down direction and the front-rear direction is defined as a left-right direction. Further, in the following description, an X1 direction side in FIG. 2 and the like, which is one side in the front-rear direction, is defined as a “front side”, and an X2 direction in FIG. 2 and the like side, which is the opposite side, is defined as a “rear” side.

The front side is a tip end side of the hand 7, and the rear side is a base end side of the hand 7. In the present embodiment, the front-rear direction (X direction) is a first direction which is a predetermined direction orthogonal to the up-down direction, and the left-right direction (Y direction) is a fourth direction which is a direction orthogonal to the up-down direction and the first direction. Further, the front side (X1 direction side) is a second direction side which is one side in the first direction, and the rear side (X2 direction side) is a third direction side which is an opposite side to the second direction side.

### [Configuration of Hand]

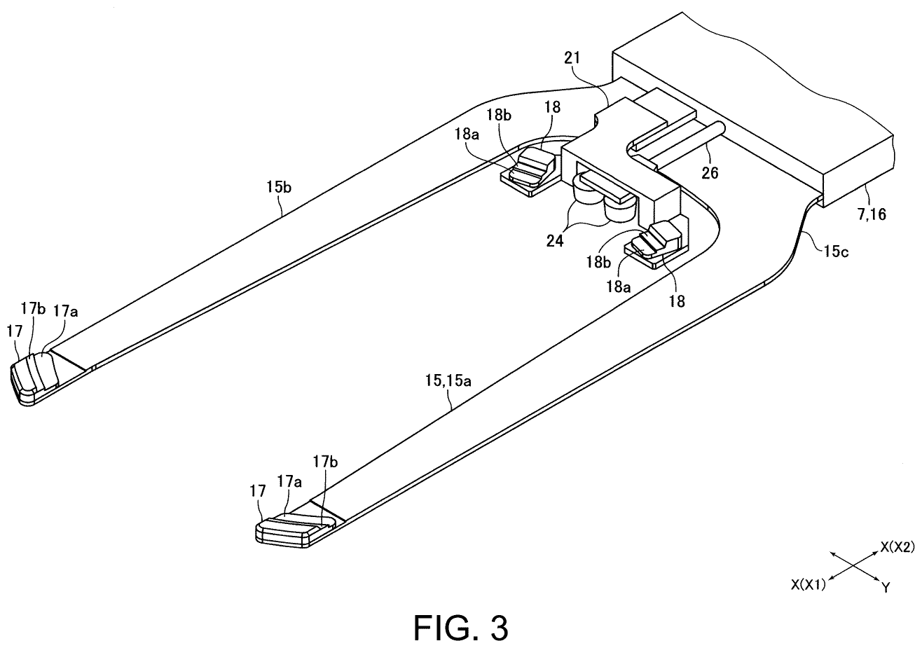

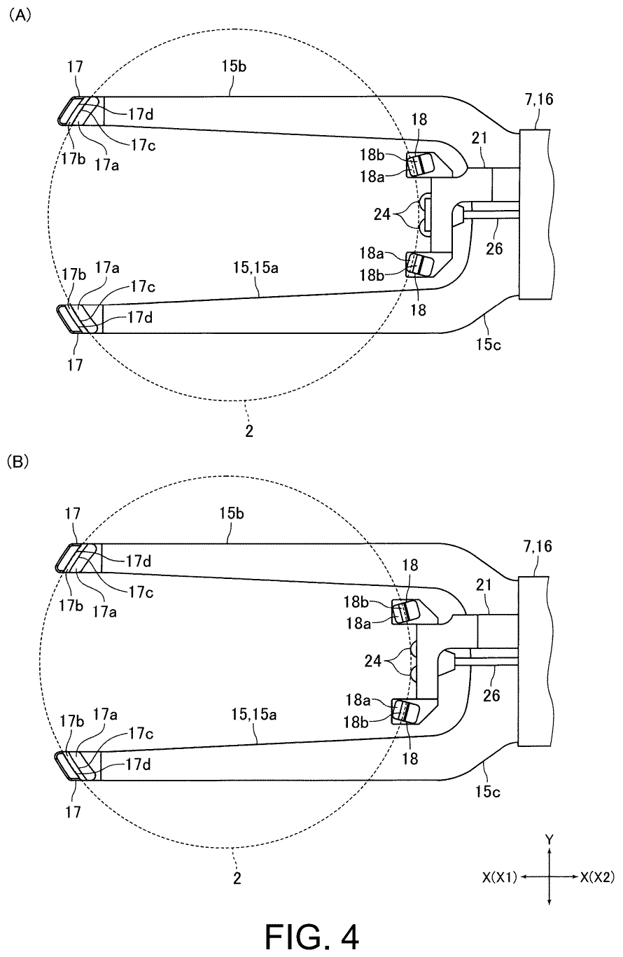

FIG. 2 is a plan view of the hand 7 illustrated in FIG. 1. FIG. 3 is a perspective view of a tip end side portion of the hand 7 illustrated in FIG. 2. FIG. 4 illustrates plan views for describing operations of a support member 18 and a roller 24 illustrated in FIG. 2.

The hand 7 includes a mounting section 15 that constitutes a front side portion of the hand 7 (i.e., a tip end side portion of the hand 7), and a hand base 16 that constitutes a rear side portion of the hand 7 (i.e., a base end side portion of the hand 7) and to which a rear end (base end) of the mounting section 15 is attached. The wafer 2 is disposed on the upper side of the mounting section 15. The hand base 16 is formed in a flat block shape having a thin thickness in the up-down direction. The hand base 16 is formed in a hollow shape. The hand base 16 is rotatably connected to the tip end side of the arm section 13. The mounting section 15 is formed in a thin flat plate shape. The thickness direction of the mounting section 15 substantially coincides with the up-down direction.

The mounting section 15 includes: a first mounting portion 15a and a second mounting portion 15b disposed in a state of being spaced apart from each other in the left-right direction, and a connecting portion 15c that connects a rear end of the second mounting portion 15b and a rear end of the second mounting portion 15b. The first mounting portion 15a and the second mounting portion 15b are formed in a rectangular shape elongated in the front-rear direction. The mounting section 15 of the present embodiment includes the first mounting portion 15a, the second mounting portion 15b and the connecting portion 15c, and the shape of the mounting section 15 when viewed from the up-down direction is a U shape. A rear end of the connecting portion 15c is fixed to the hand base 16.

Further, the hand 7 includes: a support member 17 as a first support member configured for supporting the front side portion of the wafer 2 from below, a support member 18 as a second support member configured for supporting the rear side portion of the wafer 2 from below, and a moving mechanism 19 as a first moving mechanism configured for moving the support member 18 in the front-rear direction. The hand 7 of the present embodiment includes two of the support members 17 and two of the support members 18. The wafer 2 is placed on the two support members 17 and the two support members 18. The moving mechanism 19 is configured to move the two support members 18 together in the front-rear direction.

One of the two support members 17 is fixed to the upper surface of a front end of the first mounting portion 15a, and the other support member 17 is fixed to the upper surface of a front end of the second mounting portion 15b. Namely, the support member 17 is fixed to the upper surface of the mounting section 15. The two support members 17 are disposed at the same position in the front-rear direction and disposed in a state of being spaced apart from each other in the left-right direction. In the support member 17, there are formed: a support surface 17a as a first support surface to support the wafer 2 at a predetermined first height, and a support surface 17b as a second support surface to support the wafer 2 at a second height higher than the first height.

The support surfaces 17a and 17b face upward. The height of the support surface 17b is greater than the height of the support surface 17a. The support surface 17a and the support surface 17b are adjacent to each other in a radial direction of the disk-shaped wafer 2 mounted on the hand 7 (hereinafter, this direction is referred to as a “radial direction”). The support surface 17b is disposed outside the support surface 17a in the radial direction. The support surfaces 17a and 17b are inclined surfaces that are slightly inclined downward toward the inner side in the radial direction.

An abutting surface 17c on which an end surface of the wafer 2 supported by the support surface 17a abuts is formed at a boundary between the support surface 17a and the support surface 17b. An abutting surface 17d on which the end surface of the wafer 2 supported by the support surface 17b abuts is formed on the outer side of the support surface 17b in the radial direction. Namely, the support member 17 is formed with the abutting surfaces 17c and 17d on which the end surface of the wafer 2 abuts. The abutting surfaces 17c and 17d face inward in the radial direction. The abutting surfaces 17c and 17d are inclined surfaces slightly inclined inward in the radial direction toward the upper side. The abutting surfaces 17c and 17d function to restrict the movement of the wafer 2 toward the front side.

The moving mechanism 19 includes: a holding member 21 configured to hold the two support members 18, and a drive mechanism 22 configured to move the holding member 21 in the front-rear direction. The drive mechanism 22 is accommodated in the hand base 16. The drive mechanism 22 includes, for example, a motor as a drive source and a power transmission mechanism that transmits the power of the motor to the holding member 21. The power transmission mechanism includes, for example, a ball screw. A rear end of the holding member 21 is accommodated in the hand base 16. The rear end of the holding member 21 is connected to the drive mechanism 22. A front end of the holding member 21 is disposed on the front side of the hand base 16.

The two support members 18 are fixed to the front end of the holding member 21. The two support members 18 are disposed at the same position in the front-rear direction and disposed in a state of being spaced apart from each other in the left-right direction. The support member 18 is formed with: a support surface 18a as a third support surface to support the wafer 2 at the first height together with the support surface 17a, and a support surface 18b as a fourth support surface to support the wafer 2 at the second height together with the support surface 17b.

The support surfaces 18a and 18b face upward. The height of the support surface 18a is the same as the height of the support surface 17a, and the height of the support surface 18b is the same as the height of the support surface 17b. The support surfaces 18a and 18b are adjacent to each other in the radial direction. The support surface 18b is disposed outside the support surface 18a in the radial direction. The support surfaces 18a and 18b are inclined surfaces that are slightly inclined downward toward the inner side in the radial direction.

Further, the hand 7 includes: a roller 24 as a pressing member configured to come into contact with the end surface of the wafer 2 and press the end surface of the wafer 2 from the rear side, and a moving mechanism 25 as a second moving mechanism configured to move the roller 24 in the front-rear direction. The roller 24 functions to press the end surface of the wafer 2 against the abutting surfaces 17c and 17d of the support member 17. The hand 7 of the present embodiment includes two of the rollers 24. The two rollers 24 are configured to come into contact with the end surface of the wafer 2 from the rear side. The moving mechanism 25 is configured to move the two rollers 24 together in the front-rear direction.

The moving mechanism 25 includes: a holding member 26 that is configured to rotatably hold the two rollers 24, and a drive mechanism 27 that is configured to move the holding member 26 in the front-rear direction. The drive mechanism 27 is accommodated in the hand base 16. The drive mechanism 27 includes, for example, an air cylinder as a drive source. A rear end of the holding member 26 is accommodated in the hand base 16. The rear end of the holding member 26 is connected to the drive mechanism 27. A front end of the holding member 26 is disposed on the front side of the hand base 16.

The two rollers 24 are rotatably attached to the front end of the holding member 26. A fixed shaft for supporting the roller 24 is fixed to the front end of the holding member 26. The two rollers 24 are disposed at the same position in the front-rear direction and are adjacent to each other in the left-right direction. The roller 24 is rotatable with respect to the holding member 26 with the up-down direction as the axial direction of rotation. An outer diameter of the roller 24 is gradually reduced toward the lower side. Namely, an outer peripheral surface of the roller 24 is a tapered surface.

The two support members 18 are disposed at positions shifted from the mounting section 15 when viewed from the up-down direction. Namely, the two support members 18 are disposed at positions deviated from the mounting section 15 when viewed from the up-down direction, and do not overlap the mounting section 15 in the up-down direction. Further, the two rollers 24 are disposed at positions shifted from the mounting section 15 when viewed from the up-down direction. Namely, the two rollers 24 are disposed at positions deviated from the mounting section 15 when viewed from the up-down direction, and do not overlap the mounting section 15 in the up-down direction.

To be specific, the two support members 18 and the two rollers 24 are disposed between the first mounting portion 15a and the second mounting portion 15b in the left-right direction and on the front side of the connecting portion 15c. Namely, the two support members 18 and the two rollers 24 are disposed between the rear end side portion of the first mounting portion 15a and the rear end side portion of the second mounting portion 15b in the left-right direction. The two rollers 24 are disposed between the two support members 18 in the left-right direction. Further, the two rollers 24 are disposed at the center of the hand 7 in the left-right direction. When viewed from the up-down direction, the two support members 18 are disposed symmetrically with respect to the center line of the hand 7 in the left-right direction.

One wafer 2 is placed on the hand 7. To be specific, the wafer 2 is placed on the support surface 17a of the support member 17 and the support surface 18a of the support member 18 at a first height, or the wafer 2 is placed on the support surface 17b of the support member 17 and the support surface 18b of the support member 18 at a second height. When the wafer 2 is placed on the support surfaces 17a and 18a, the support member 18 is disposed at a position where the wafer 2 can be placed on the support surface 18a (see (a) of FIG. 4). When the wafer 2 is placed on the support surfaces 17b and 18b, the support member 18 is disposed at a position where the wafer 2 can be placed on the support surface 18b (see (b) of FIG. 4).

When the roller 24 moves to the front side in a state where the wafer 2 is placed on the support surfaces 17a and 18a, the abutting surface 17c and the roller 24 come into contact with the end surface of the wafer 2, and the wafer 2 is held at a constant position in the horizontal direction. Further, when the roller 24 moves to the front side in a state where the wafer 2 is placed on the support surfaces 17b and 18b, the abutting surface 17d and the roller 24 come into contact with the end surface of the wafer 2, and the wafer 2 is held at a constant position in the horizontal direction.

### [Main Effects of Present Embodiment]

As described above, in this embodiment, the support member 18 is disposed at a position shifted from the mounting section 15 when viewed from the up-down direction, and does not overlap the mounting section 15 in the up-down direction. Therefore, in the present embodiment, even when the hand 7 includes the support member 18 to support the wafer 2 from below at two different heights (i.e., the first height and the second height), it is possible to make the hand 7 thinner in the up-down direction as compared with a case where the support member 18 overlaps the mounting section 15 in the up-down direction.

Further, in the present embodiment, the roller 24 is disposed at a position shifted from the mounting section 15 when viewed from the up-down direction, and does not overlap the mounting section 15 in the up-down direction. Therefore, in the present embodiment, even when the hand 7 includes the roller 24, it is possible to make the hand 7 thinner in the up-down direction. Further, in the present embodiment, the support member 18 and the roller 24 are disposed between the first mounting portion 15a and the second mounting portion 15b in the left-right direction and on the front side of the connecting portion 15c. Therefore, it is possible to reduce the size of the hand 7 in the front-rear and left-right directions.

In the present embodiment, the support surface 18a to support the wafer 2 at a first height and the support surface 18b to support the wafer 2 at a second height are formed on the support member 18. Therefore, in the present embodiment, it is possible to reduce the number of components of the hand 7 and to narrow an installation space of the support member 18, as compared with a case where a member on which the support surface 18a is formed and a member on which the support surface 18b is formed are separately provided.

### OTHER EMBODIMENTS

Although the above-described embodiment is an example of the preferred embodiments of the present invention, it is not limited thereto, and various modifications may be implemented without changing the gist of at least an embodiment of the present invention.

In the above-described embodiment, the two rollers 24 may be disposed outside the two support members 18 in the left-right direction. In this case, the two rollers 24 may be disposed between the first mounting portion 15a and the second mounting portion 15b in the left-right direction, or may be disposed outside the mounting section 15 in the left-right direction. Further, in the above-described embodiment, the two support members 18 may be disposed outside the mounting section 15 in the left-right direction. Even in these cases, the two support members 18 and the two rollers 24 are disposed at positions shifted from the mounting section 15 when viewed from the up-down direction, and do not overlap the mounting section 15 in the up-down direction.

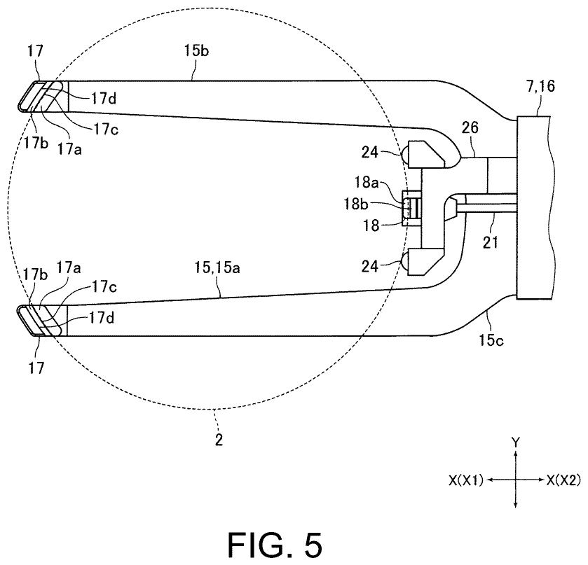

In the above-described embodiment, as illustrated in FIG. 5, the number of support members 18 included in the hand 7 may be one. In this case, the support member 18 is disposed at the center of the hand 7 in the left-right direction. The two rollers 24 are disposed outside the support member 18 in the left-right direction. In this case, as illustrated in FIG. 5, the two rollers 24 may be disposed between the first mounting portion 15a and the second mounting portion 15b in the left-right direction, or may be disposed outside the mounting section 15 in the left-right direction. Even in this case, the support member 18 and the two rollers 24 are disposed at positions shifted from the mounting section 15 when viewed from the up-down direction, and do not overlap the mounting section 15 in the up-down direction. In FIG. 5, the same reference signs are used to denote the components similar to those of the embodiment described above.

In the above-described embodiment, a support surface to support the wafer 2 at a third height higher than the second height may be formed on the support members 17 and 18. Further, a support surface to support the wafer 2 at a fourth height higher than the third height may be formed on the support members 17 and 18. Namely, in the above-described embodiment, the two support surfaces 17a, 17b, 18a, and 18b having different heights from each other are formed on the support members 17 and 18, but three or more support surfaces having different heights from each other may be formed on the support members 17 and 18. Namely, the support members 17 and 18 may support the wafer 2 from below at three or more different heights.

In the above-described embodiment, the number of rollers 24 included in the hand 7 may be one. Further, in the above-described embodiment, the pressing member that comes into contact with the end surface of the wafer 2 and presses the end surface of the wafer 2 against the abutting surfaces 17c and 17d of the support member 17 may not be a roller. For example, the pressing member may be a columnar member that is fixed to the front end of the holding member 26. Further, in the above-described embodiment, the hand 7 may not include the roller 24 and the moving mechanism 25. In this case, for example, suction holes to suck the wafer 2 placed on the support surfaces 17a, 17b, 18a, and 18b are formed in the support members 17 and 18. Further, in this case, the abutting surfaces 17c and 17d may not be formed on the support member 17.

Further, in the above-described embodiment, the robot 1 may include two hands 7 that are rotatably connected to the tip end side of the arm 8. In this case, for example, two arms 8 overlap each other in the up-down direction. When the robot 1 includes the two hands 7, for example, the arm 8 may include a common arm section, which is formed in a V shape and has a central part rotatably connected to the main-body section 9, a first arm section having a base end side rotatably connected to one end side of the common arm section, and a second arm section having a base end side rotatably connected to an other end side of the common arm section. In this case, the hand 7 is rotatably connected to each of the tip end side of the first arm section and the tip end side of the second arm section.

Further, in the above-described embodiment, the robot 1 may include the two arms 8 whose base end sides are rotatably connected to the main-body section 9. In this case, the hand 7 is rotatably connected to the tip end side of each of the two arms 8. Still further, in the above-described embodiment, the arm 8 may include two arm sections, or may include four or more arm sections. In the above-described embodiment, the conveyance object that is to be conveyed by the robot 1 may be other than the wafer 2.

Further, the industrial robot to which at least of an embodiment of the present invention is to be applied may be a robot other than a horizontal multi-joint industrial robot. For example, the industrial robot to which at least an embodiment of the present invention is applied may be an industrial robot including an arm to which the hand 7 is connected in such a way that the hand 7 can linearly reciprocate, a main-body section to which the arm is rotatably connected, and a linear drive section that linearly reciprocates the hand 7 with respect to the arm.

What is claimed is:

1. A hand of an industrial robot that conveys a conveyance object, wherein
a predetermined direction orthogonal to an up-down direction is defined as a first direction, one side of the first direction is defined as a second direction side, and a side opposite to the second direction side is defined as a third direction side,
wherein the hand comprises:
a mounting section that constitutes a portion of the hand on the second direction side and of which the conveyance object is disposed on an upper side;
a hand base that constitutes a portion of the hand on the third direction side and to which an end of the mounting section on the third direction side is attached;
a first support member that is fixed to an upper surface of the mounting section and supports a portion of the conveyance object on the second direction side from below;
a second support member that supports a portion of the conveyance object on the third direction side from below; and
a first moving mechanism that moves the second support member in the first direction,
wherein
the first support member is formed with a first support surface to support the conveyance object at a predetermined first height and a second support surface to support the conveyance object at a second height higher than the first height,
the second support member is formed with a third support surface to support the conveyance object at the first height and a fourth support surface to support the conveyance object at the second height, and
the second support member is disposed at a position shifted from the mounting section when viewed from the up-down direction.

2. The hand according to claim 1, further comprising:
a pressing member that is configured to come into contact with an end surface of the conveyance object and press the conveyance object from the third direction side; and
a second moving mechanism that is configured to move the pressing member in the first direction,
wherein
the first support member is formed with an abutting surface on which an end surface of the conveyance object abuts, and
the pressing member is configured to press the end surface of the conveyance object against the abutting surface, and is disposed at a position shifted from the mounting section when viewed from the up-down direction.

3. The hand according to claim 2, wherein,
a direction orthogonal to the up-down direction and the first direction is defined as a fourth direction,
the mounting section includes:
a first mounting portion and a second mounting portion that are disposed in a state of being spaced apart from each other in the fourth direction; and
a connecting portion that connects an end of the first mounting portion on the third direction side and an end of the second mounting portion on the third direction side, wherein
the second support member and the pressing member are disposed between the first mounting portion and the second mounting portion in the fourth direction and on the second direction side of the connecting portion.

4. The hand according to claim 3, wherein
the hand comprises two of the second support members disposed in a state of being spaced apart from each other in the fourth direction,
wherein
the pressing member is disposed between the two second support members in the fourth direction.

5. An industrial robot comprising:
the hand according to claim 1;
an arm to which the hand is connected; and
a main-body section to which the arm is connected.

6. An industrial robot comprising:
the hand according to claim 2;
an arm to which the hand is connected; and
a main-body section to which the arm is connected.

7. An industrial robot comprising:
the hand according to claim 3;
an arm to which the hand is connected; and
a main-body section to which the arm is connected.

8. An industrial robot comprising:
the hand according to claim 4;
an arm to which the hand is connected; and
a main-body section to which the arm is connected.
